(19) United States
(12) Patent Application Publication
(10) Pub. No.: US 2015/0187900 A1
(43) Pub. Date: Jul. 2, 2015

(54) COMPOSITE MATERIALS FOR USE IN SEMICONDUCTOR COMPONENTS

(71) Applicants: Sadasivan Shankar, Cupertino, CA (US); MARK BOHR, Aloha, OR (US); Michael Haverty, Mountain View, CA (US)

(72) Inventors: Sadasivan Shankar, Cupertino, CA (US); MARK BOHR, Aloha, OR (US); Michael Haverty, Mountain View, CA (US)

(21) Appl. No.: 14/140,629

(22) Filed: Dec. 26, 2013

(51) Int. Cl. H01L 29/51; H01L 21/28; H01L 27/088

(52) U.S. Cl. CPC H01L 29/513; H01L 27/088; H01L 21/28194

(57) ABSTRACT

An integrated circuit including a transistor, wherein the transistor includes a substrate including a surface, a gate oxide deposited on the substrate surface and a gate deposited on the gate oxide. The gate oxide includes one or more dielectric domains and a band gap matrix. The dielectric domains includes a first material and the band gap matrix includes a second material, wherein a dielectric constant of the first material is greater than a dielectric constant of the second material and a band gap of the first material is less than a band gap of the second material.

### FIELD

The present disclosure is directed to composite material for semiconductor components and, in particular, for use as a gate oxide in planar and non-planar transistors.

### BACKGROUND

An integrated circuit is set of electronic circuits formed on a semiconductor. Integrated circuits include transistors as well as a variety of other electronic components, depending on the end use of the circuit. As features of integrated circuits become smaller and transistor density increases, various complications arise. For example, depending on the construction of an integrated circuit, transistors typically include a semiconductor, a metal gate, and a gate oxide or insulator arranged between the semiconductor and the gate.

As the gate oxide becomes thinner, the effective dielectric constant of the gate oxide decreases. This leads to an increase in the power required to operate the transistors due to increased gate oxide leakage current as well as a reduction in reliability. While relatively high dielectric materials provide increased gate capacitance, these materials tend to exhibit relatively lower band gaps. Accordingly, high dielectric materials are selected from group IIB and group IV oxides taking into account the trade-off between the dielectric constant and band offset. Thus, room remains for the development of and improvement in materials directed at maintaining a relatively high band gap and a relatively high dielectric constant.

### BRIEF DESCRIPTION OF THE DRAWINGS

The above-mentioned and other features of this disclosure, and the manner of attaining them, may become more apparent and better understood by reference to the following description of embodiments described herein taken in conjunction with the accompanying drawings, wherein:

FIG. 1 illustrates an embodiment of a planar transistor formed on a substrate incorporating a composite material as the gate oxide layer;

FIG. 2 illustrates an embodiment of a non-planar transistor formed on a substrate incorporating a composite material as the gate oxide layer;

FIG. 3 illustrates a plot of dielectric constant versus band gap for a number of dielectric materials;

FIG. 4 illustrates an embodiment of a composite material including nanoparticles forming dielectric domains within a band gap matrix material;

FIG. 5a illustrates a top view of an embodiment of a composite material including a dielectric domain provided as a planar laminate with a band gap matrix material;

FIG. 5b illustrates a side view of a cross-section of the embodiment of FIG. 5a;

FIG. 5c illustrates a top view of an embodiment of a composite material include an electric domain provided as a columnar laminate with a band gap matrix material;

FIG. 5d illustrates a side view of a cross-section of the embodiment of FIG. 5c;

FIG. 6a illustrates a top view of an embodiment of a composite material including dielectric domains provided in alternating layers with a band gap material matrix;

FIG. 6b illustrates a side view of a cross-section of the embodiment of FIG. 6a;

FIG. 6c illustrates a top view of an embodiment of a composite material including dielectric domains provided in alternating layers with a band gap material matrix;

FIG. 6d illustrates a side view of a cross-section of the embodiment of FIG. 6c;

FIG. 7a illustrates a top view of an embodiment of a composite material including dielectric domains embedded in a band gap matrix material;

FIG. 7b illustrates a side cross-sectional view of the composite material of FIG. 7a;

FIG. 8 illustrates a method of forming a transistor including the composite materials herein;

FIG. 9 illustrates a plot of the dielectric constant of varying percent of titanium present in HfTiO₂;

FIG. 10 illustrates various crystallographic structures for phases found in HfTiO2 compositions for varying amounts of Hf; and

FIG. 11 illustrates a thermodynamic phase diagram for Ti-Hf alloys.

### DETAILED DESCRIPTION

As noted above, as integrated circuits are scaled down and feature size decreases, various complications arise with respect to material behavior. For example, as gate oxides become thinner, the effective dielectric constant of the gate oxide decreases and leads to an increase in leakage current as well as a reduction in reliability. The present disclosure is directed to composite materials for use in semiconductor components as dielectric materials.

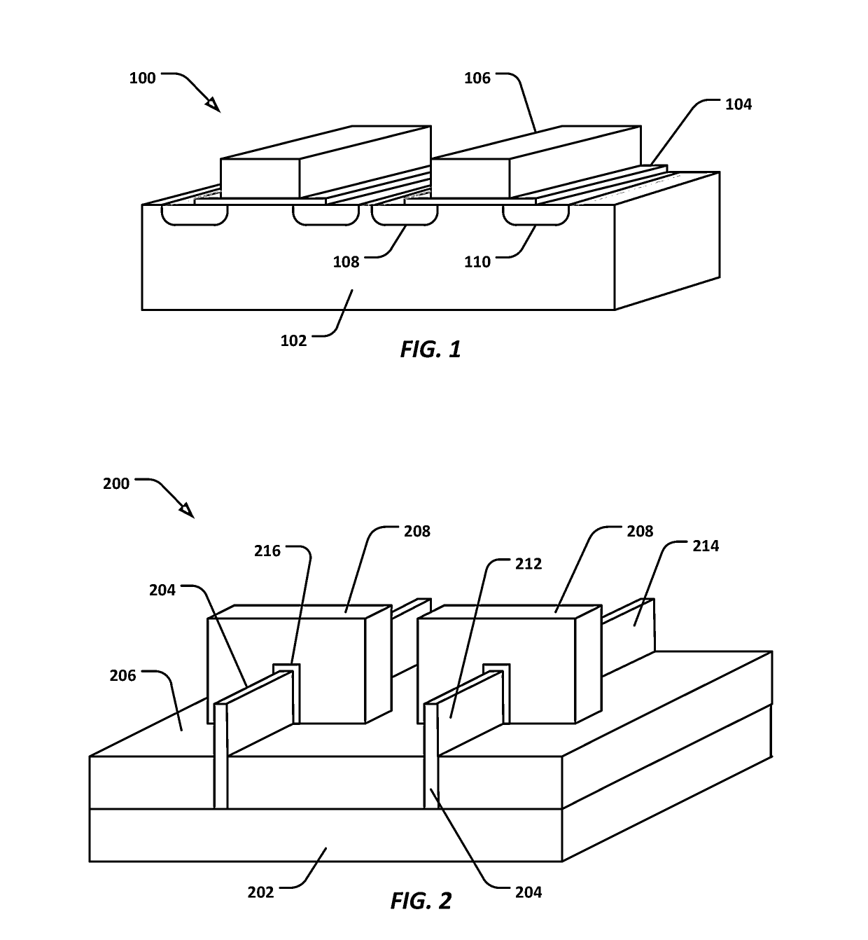

In particular embodiments, the composite materials herein are used as gate oxides in transistors in either planar (2D) and non-planar, three-dimensional (3D), metal-oxide semiconductors, illustrated in FIGS. 1 and 2, respectively. As seen in the figures, in planar designs gates lay flat against the surface of the substrate, whereas in non-planar designs, the substrate includes fins extending therefrom and gates extend up both sides and over the fin.

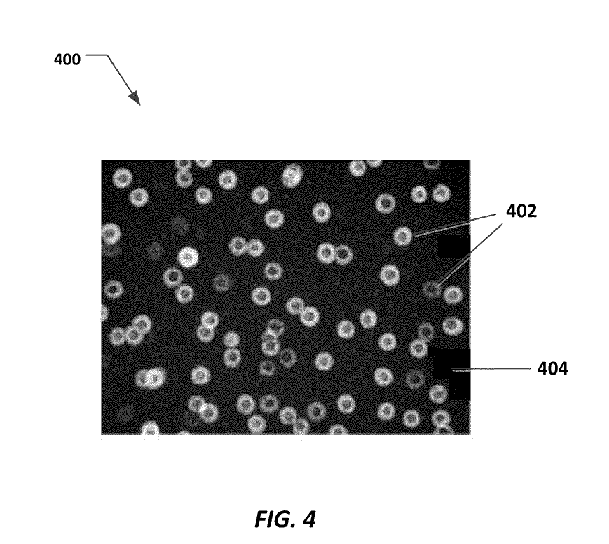

FIG. 1 illustrates an embodiment of a planar transistor 100 of an integrated circuit formed on a substrate 102. The substrate is formed, for example from silicon, silicon dioxide, gallium arsenide, alloys of silicon and germanium, or alloys thereof. In addition, the substrate may be doped. Disposed on the substrate 102 surface is a gate oxide 104, which is formed by patterning the substrate and then forming the gate oxide using one or more of the methods discussed further herein with reference to FIGS. 4 through 7b. Deposited on the gate oxide 104 is a metal gate 106. The metal gate is formed from Ta, Ti, TaN, Nb, Mo, WN/RuO₂. The metal gate is deposited using patterning and deposition techniques known to persons of ordinary skill in the art, including for example, chemical or physical vapor deposition. A source 108 and drain 110 are also provided. The source and drain are formed in the surface of the substrate prior to oxide formation by doping the substrate using patterning and ion implantation or other techniques as known to those of ordinary skill in the art.

FIG. 2 illustrates an embodiment of a non-planar transistor 200 of an integrated circuit formed on a substrate 202. Again the substrate is formed, for example, from silicon, silicon dioxide, gallium arsenide, alloys of silicon and germanium, etc. Projecting from the substrate 202 is a fin 204 that extends upward from the substrate and, in embodiments, is formed by etching the substrate surface. Surrounding the base of the fin 204 is an insulating layer 206, such as an oxide layer, which may be deposited via chemical vapor deposition or physical vapor deposition on the substrate surface, or grown on the substrate surface. A gate 208 extends over a portion of the fin 204 and is deposited using patterning and deposition techniques known to persons of ordinary skill in the art. A gate oxide is formed between the fin 204 and the gate 208, prior to depositing the gate using the techniques described further herein. As illustrated, three surfaces of the fin 204 contact the gate 208, providing a tri-gate transistor. However, in other embodiments, less than three sides are present, such as two sides, or more than three sides are present, such as four or five sides. On one side of the gate 208, the fin 204 includes a source 212, and on the other side of the gate 208, the fin 204 includes a drain 214. The source 212 and drain 214 are formed by doping the fin 204, via ion implantation or other processes known to a person having ordinary skill in the art. In one embodiment, ion implantation is performed before formation of the gate.

In further embodiments, the composite material is used in gate oxides that extend into trenches formed in a substrate. In such configurations, the gate oxide is present at and below the surface of the substrate, and the source and drain are formed at or on the substrate surface. The composite material may also be utilized in other gate configurations as well as for other applications in an integrated circuit.

In embodiments, the composite material includes one or more dielectric domain(s) provided within a band gap matrix. The dielectric domain(s) include(s) a material that exhibits a relatively higher dielectric constant than the band gap matrix material, whereas as the band gap matrix includes a material that exhibits a relatively higher band gap than the dielectric domain material. In some embodiments, the dielectric domain(s) is (are) embedded in band gap matrixes. In other embodiments, dielectric domains are layered with the band gap matrix material.

The dielectric constant of a material is understood as it's relatively permittivity, κ, i.e., the ratio of the permittivity of the material to the permittivity of free space. Permittivity is understood as the resistance to forming an electric field in a medium. In general, increasing dielectric constant provides increased gate capacitance.

In embodiments, the difference in dielectric constant between the dielectric domain material and the band gap matrix material is in the range of 10 or more, such as in the range of 10 to 250 and, in particular examples, in the range of 20 to 40. Materials suitable for use as dielectric domains include, for example, compositions selected from Group II, Group III and Group IV and lanthanide metal oxides such as lanthanum oxide (La₂O₃), titanium dioxide (TiO₂), tantalum pentoxide (Ta₂O₅), hafnium titanate (HfTiO₂), barium titanate (BaTiO₃), praseodymium oxide (Pr₂O₃), and perovskite oxides such as strontium titanate (SrTiO₃). In particular embodiments, the dielectric domain material exhibits a dielectric constant of 20 or greater, when measured at a temperature of 302 K. For example, the dielectric constant is in the range of 40 to 350, including all values and ranges therein, such as 40 to 100, when measured at a temperature of 302 K. On the other hand, the band gap matrix material, in embodiments of the above, exhibits a dielectric constant of 25 or less, such as in the range of 3 to 25, when measured at a temperature of 302 K, including all values and ranges therein, such as 3 to 20, 3 to 15, etc.

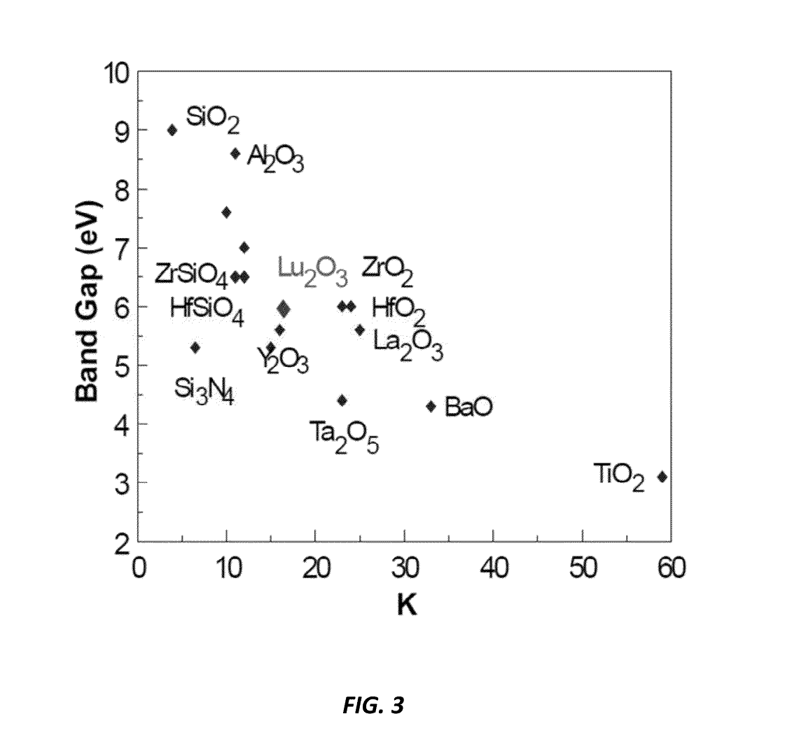

A single dielectric material is used to form the one or more domains; or, alternatively, two or more dielectric materials are used to form two or more domains. However, as noted above, materials exhibiting a relatively high dielectric constant tend to exhibit a relatively lower band gap. To illustrate, reference is made to FIG. 3, which includes a graph of dielectric constant versus band gap for a number of materials.

Band gap is understood as the difference in energy between the valence band and the conduction band of a solid material. Electron states do not exist between these energy values of the valence and conduction bands. As band gap increases and the band gap value becomes higher, the material generally exhibits relatively lower tunneling leakage current (below 1 A/cm²), reducing gate-induced drain leakage and passive power dissipation.

Another factor that affects the tunneling leakage current is the band offset at the junction between the dielectric material and the semiconductor, ie., the line-up of the band gap edges of the dielectric material with the band gap edges of the semiconductor. While in some cases a dielectric may have a sufficient band gap, if the band gap is centered around the band edge of the semiconductor then the effective band offset for one type of carrier (electrons or holes) may be relatively low. In selecting a dielectric material having a higher band gap, the chances of the band gap being centered around the band edge of the semiconductor is reduced, reducing tunneling and leakage.

The difference in band gap between the band gap matrix material and the dielectric domain material is in the range of 2 eV or more, such as in the range of 3 eV to 6 eV, including all values and ranges therein. Examples of relatively high band gap materials include compositions selected from Group II, Group III and Group IV and lanthanide metal oxides, silicates, or nitrides such as silicon oxide (SiO₂), strontium oxide (SrO), calcium oxide (CaO), gadolinium oxide (Gd₂O₃), barium oxide (BaO), yttrium oxide (Y₂O₃), hafnium oxide (Hf0₂), lanthanum oxide (La₂O₃), lutetium oxide (Lu₂O₃), aluminum oxide (Al₂O₃), zirconium dioxide (ZrO₂), zirconium silicate (ZrSiO₄), silicon nitride (Si₃N₄), etc. In particular embodiments, the band gap matrix material exhibits a band gap of 5.0 eV or greater, such as in the range of 5.0 (eV) to 10.0 (eV) as measured at 300 K. On the other hand, the dielectric material, in embodiments of the above, exhibits a band gap of 5 eV or less, such as in the range of 2 eV to 5 eV, including all values and ranges therein. As may be appreciated, a number of the band gap materials herein are understood to exhibit chemical stability relative to the substrate and gate materials.

In particular examples, the dielectric domain material and band gap materials selected are isovalent or exhibit a similar chemical reactivity, wherein the oxidation state of the metals are within +/−1. In one example, one or more TiO₂ domains are present in an HfO₂ matrix. In another example, one or more La₂O₃ domains are present in Al₂O₃ matrix.

The dielectric domain material is present in the total composition including both the dielectric domain material and band gap matrix material at a level of less than 50 mass percent, including all values and ranges from 1 mass percent to 49 mass percent, such as 10 mass percent to 45 mass percent, 25 mass percent to 45 mass percent, etc. Given the larger mass percent of band gap material, the band gap material is referred to herein as being the matrix material, although the domain material is not, in all embodiments, completely encompassed on all surfaces by the matrix material.

In embodiments, the size of largest dimension of the dielectric domains is in the range of 0.2 nm to 15 nm, including all values and ranges therein, such as 0.2 nm, 1 nm, etc. It is noted that the smaller the domain size, the smaller the observed band gap of the dielectric domain. In embodiments, the domains are in the form of nanoparticles, one or more layers laminated between band gap matrix material, or intermixed between two isovalent metallic atoms as described further below.

FIG. 4 illustrates an embodiment of a composite material 400, wherein the dielectric domains are dispersed as nanoparticles 402 in a band gap matrix 404. As illustrated, the nanoparticles 402 are formed of titanium oxide (TiO₂) and the matrix 404 is hafnium oxide (HfO₂). In other embodiments, other domain and matrix compositions are utilized.

In embodiments, the composite is formed by depositing a layer of the band gap matrix by chemical vapor deposition or atomic layer deposition. Nanoparticles of the dielectric domains are then deposited over the band gap matrix by casting. The casting solvent is evaporated or otherwise removed. This is repeated until a desired thickness of composite material has been achieved.

Atomic layer deposition (ALD) is understood as a process where precursors are individually metered into a vacuum chamber holding the substrate under vacuum therein. A first precursor is deposited on the surface, followed by a purging of excess first precursor. Then the second precursor is deposited on the surface. The second precursor then reacts with the first precursor to form the desired product on the surface of the substrate.

For example, in the case of HfO₂, hafnium chloride HfCl₄ (ad.) is deposited as a first precursor on the substrate. Excess hafnium chloride is purged from the vacuum chamber and then an oxidizer such as water vapor or hydrogen peroxide is introduced into the vacuum chamber as a second precursor. The precursors react forming a layer of hafnium oxide on the surface of the substrate.

The layers are built individually until a desired thickness is reached. The coatings developed using atomic layer deposition or other chemical vapor deposition techniques herein tend to be conformal, i.e., exhibit relatively uniform in thickness on all surfaces, regardless of the orientation of the surfaces to the substrate. In embodiments, the thickness at any location varies less than +/−30% of the average coating thickness.

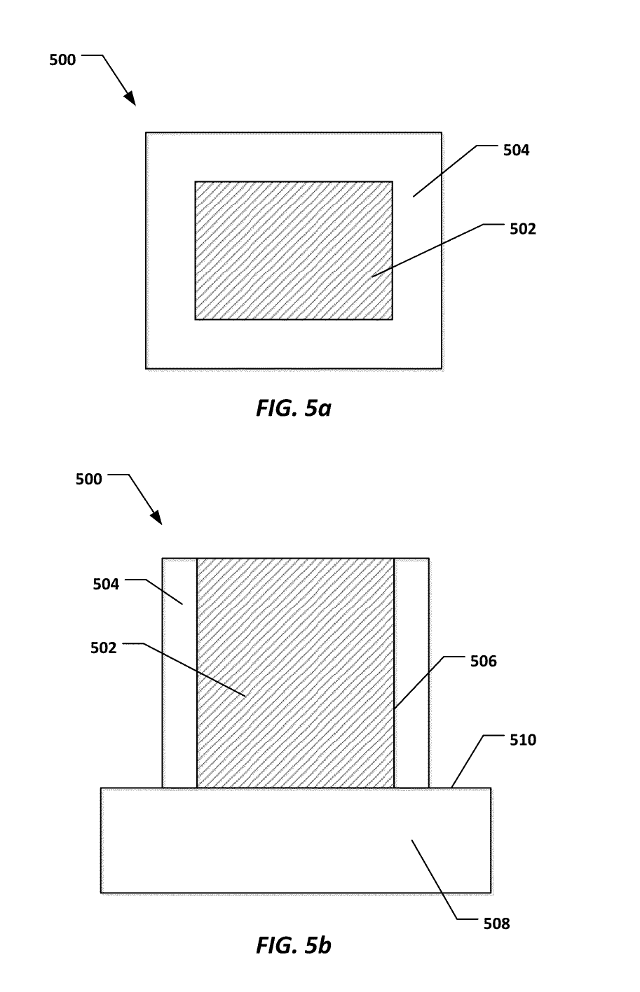

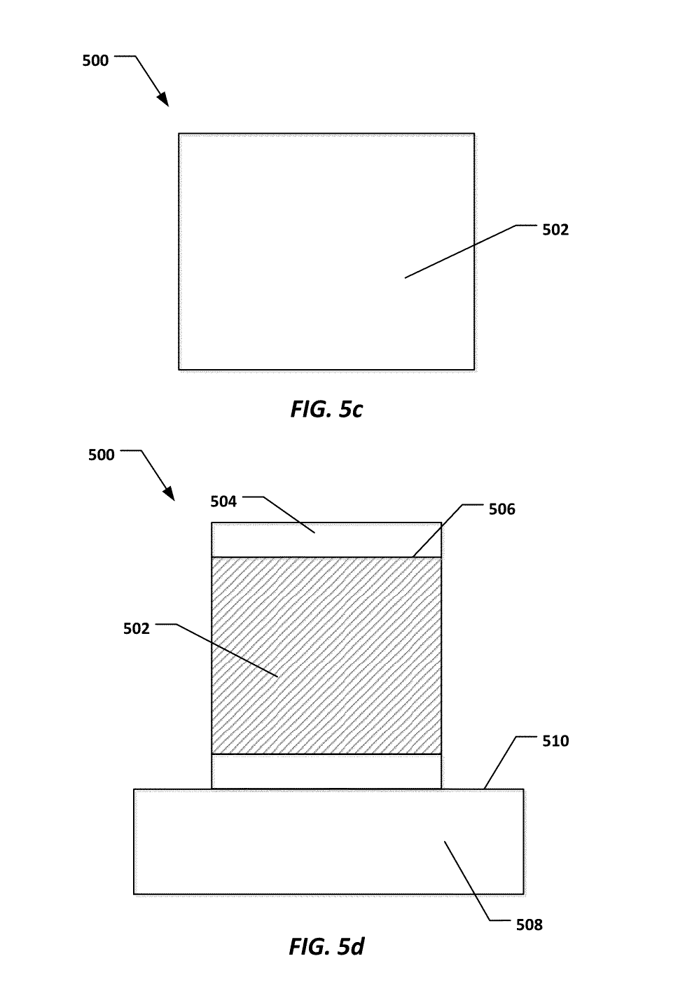

FIGS. 5a and 5b illustrate an embodiment of a composite material 500 where the domain material 502 and matrix material 504 form a laminate. The laminate is oriented perpendicular or generally perpendicular to the substrate, that is the interfaces 506 between the layers 502, 504 are perpendicular to the substrate 508 as illustrated in FIG. 5b. However, in embodiments, the interfaces 506 between the laminate layers 502, 504 may be oriented at an angle greater than 0 and up to 90 degrees relative to the substrate surface 510, such as 1 degree to 90 degrees, including all values and ranges therein, such as 45 to 90 degrees. To achieve orientations other than perpendicular or parallel, self-assembly, or wafer tilting techniques may be used to achieve the inclined layers. FIGS. 5c and 5d illustrate orientations that are parallel to the substrate 508, wherein the interfaces 506 between the layers 502, 504 are parallel to the substrate 508. In particular embodiments, such as in non-planar fin or nanowire transistors, as the gate oxide wraps around a portion, or all of the gate, the orientation of the layers may change relative to the substrate and both perpendicular and parallel orientations may be present.

In embodiments, the band gap matrix is deposited in a trench formed in a resist deposited on the substrate. The band gap matrix is formed using atomic layer deposition (ALD) or another vapor deposition process. During deposition, a layer of band gap material forms a conformal coating on the walls of the resist as well as on the surface of the substrate resulting in the formation of a trench of the band gap matrix material. If desired, in particular embodiments, the band gap matrix material is etched using a line of sight process, such as a dry etching process. This removes a portion of the band gap matrix material between the walls at the bottom of the trench.

The dielectric domain is then deposited within the trench. In embodiments, a line of sight method of deposition, such as physical vapor deposition is used to deposit the dielectric domain. Alternatively, a chemical vapor deposition method, such as ALD, is used to deposit the dielectric domain. If desired, a portion of the dielectric domain material is etched or otherwise removed and a layer of the band gap matrix is also deposited over the band gap trench filled with the dielectric domain material. During the process, the surface is optionally polished using techniques such as chemical mechanical planarization to remove excess band gap matrix and dielectric domain material. Excess resist is also polished or ashed off.

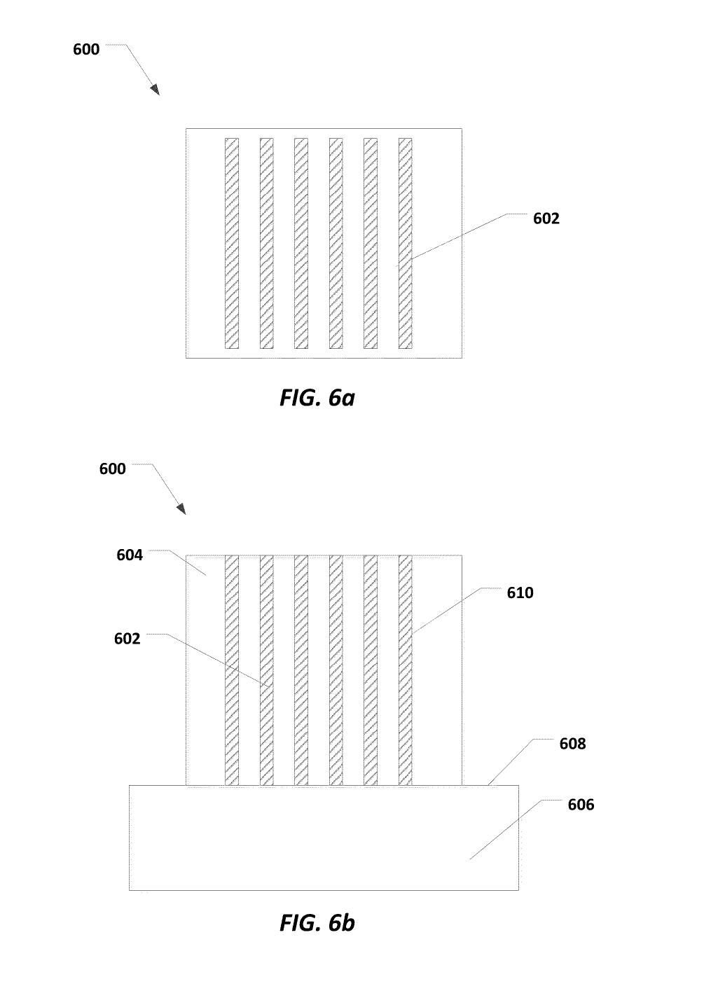

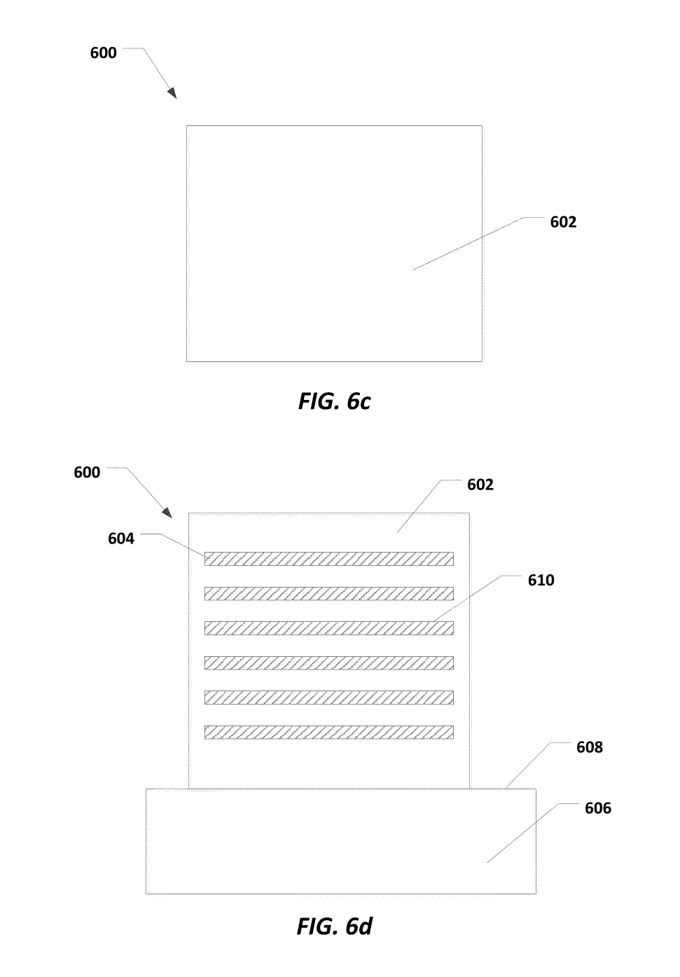

FIGS. 6a and 6b illustrate another embodiment of a composite material 600 where domain material 602 and matrix material 604 form a laminate over a substrate 606. The layers are vertically oriented relative to the surface 608 of the substrate 606, wherein the interface 610 between the layers 602, 604 is perpendicular or generally perpendicular to the substrate surface 608. However, in embodiments, the interfaces 610 between the laminate layers 602, 604 are oriented at an angle greater than 0 and up to 90 degrees relative to the substrate surface 608, such as from 1 degree to 90 degrees, including all values and ranges therein, such as 45 degrees to 90 degrees. Similarly, FIGS. 6c and 6d illustrate the composite material 600 where the interfaces 610 between the layers of the domain material 602 and matrix material 604 are oriented parallel to the substrate surface 608.

In embodiments, a layer of the band gap matrix is deposited in a trench formed in a resist using a chemical vapor deposition method such as atomic layer deposition (ALD). The band gap matrix material is then selectively etched to form trenches therein. Various forms of patterning can be used such as extreme ultraviolet lithography, e-beam lithography, x-ray lithography, deep x-ray lithography, or patterning techniques as well as employing self-assembling material such as polymer materials as a resist and removing one of the polymer components. The band gap matrix material may then be etched in the patterned areas creating trenches in the band gap matrix material. The dielectric domains are then deposited in the trenches. A chemical vapor deposition method, such as ALD, is used to deposit the dielectric domains. Then, in embodiments of the above, a layer of the band gap matrix is deposited over the band gap trenches filled with the dielectric domain. The surface is polished using techniques such as chemical mechanical planarization to remove excess band gap matrix and dielectric domain material. In embodiments, any remaining resist is ashed off.

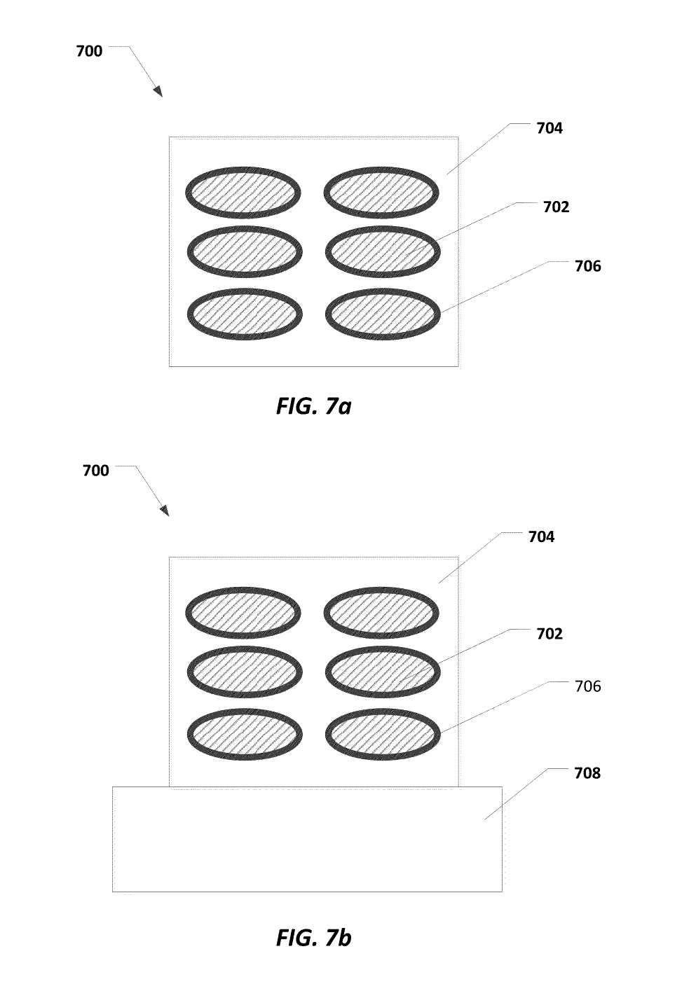

FIGS. 7a and 7b illustrate a further embodiment of a composite material 700 deposited on a substrate 708 wherein dielectric domains 702 are dispersed in a band gap matrix 704. As illustrated the domains are uniformly dispersed in the matrix or randomly dispersed in the matrix. In embodiments, isovalent substitutions occur, such that the dielectric domain incorporates metal atoms from the band gap matrix material or vice versa, particularly at the interface 706 between the domain material and the matrix material. For example, in the case where HfO₂ forms the band gap matrix and TiO₂ form the dielectric domains, HfTiO₂ may form in regions around the domains. Additionally, or alternatively, domains of HfTiO₂ may form. Formation of the various compositions depends on the flow rate and deposition conditions used in the process.

In embodiments, a layer of band gap matrix material is optionally deposited by a chemical vapor deposition, such as ALD, forming a conformal layer of the band gap matrix material. This is followed by the deposition of a mixture of both the dielectric domain material and the band gap matrix material forming domains of the dielectric material within the band gap matrix material. An additional layer of the band gap matrix material is then optionally formed.

Other methods of forming the composite materials described herein are understood to those having ordinary skill in the art. These methods depend on the feature geometry and material constraints, including reactivity.

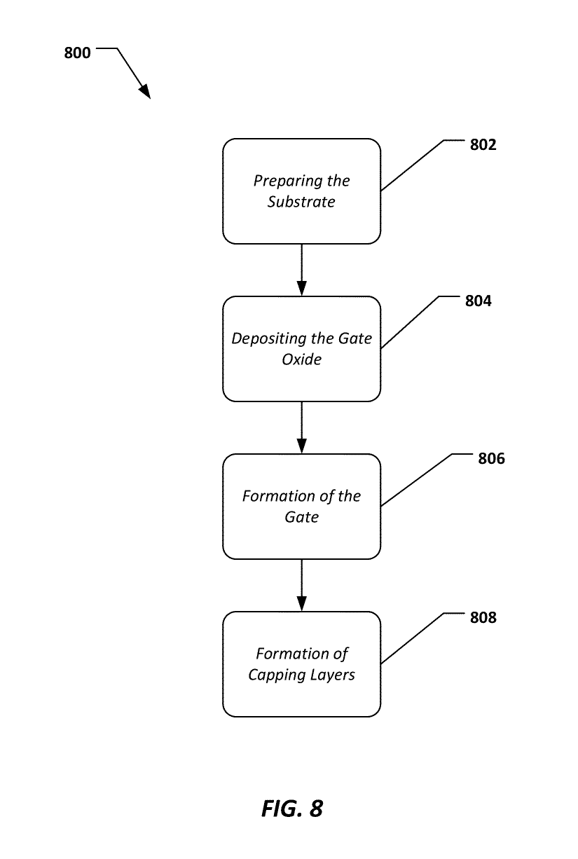

In general, an embodiment of a method of forming the gate oxides herein is illustrated in FIG. 8. The method 800 includes preparing a substrate surface for receiving the composite material 802. This step optionally includes, etching fins into a substrate and doping the fins or substrate surface to form the source and drain regions of the transistor. Once the substrate surface is prepped, the gate oxide is deposited on the substrate surface 804 using the methods described above, or others known to persons of ordinary skill in the art. After the gate oxide is deposited, the gate is then formed over the gate oxide 806. Optionally, capping layers, such as diffusion barriers, adhesion barriers, or insulating layers are formed 808. This is then followed by back end of line processes and packaging.

Integrated circuits incorporating the composite materials described above are, in embodiments, used to form complementary metal-oxide semiconductors (CMOS), which is a type of semiconductor that includes negative polarity (NMOS) and positive polarity (PMOS) metal oxide transistors. While use of the composite material in gate oxides for transistors is described herein, the composite materials may be incorporated as an insulating material in other components as well, such as diodes, power sources, resistors, capacitors, inductors, sensors, transceivers, receivers, antenna, etc. Or such components may be present in a device incorporating the composites as dielectric layers. The integrated circuits may be used in a number of applications, such as microprocessors, opto-electronics, logic blocks, audio amplifiers, etc. The integrated circuits may be employed as part of a chipset for executing one or more related functions in a computer as well as in mobile devices such as mobile phones, tablets, laptops, etc.

### EXAMPLES

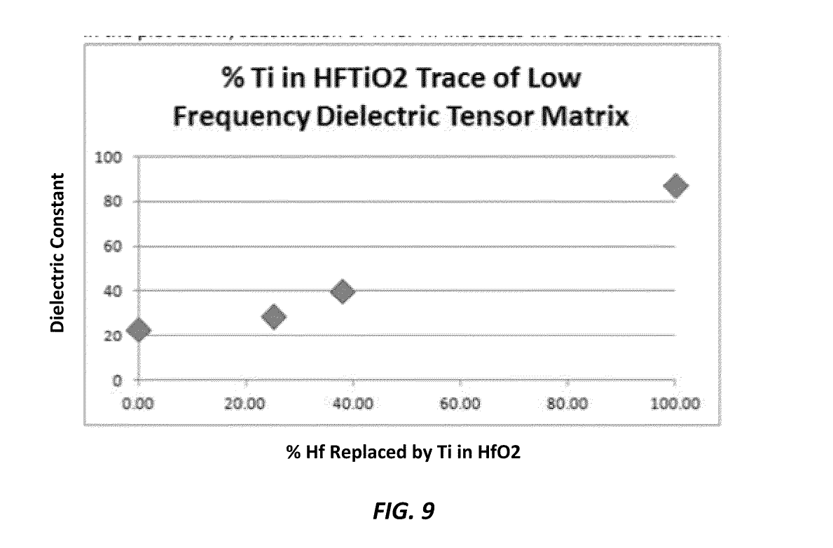

To determine the effect of titanium substitutions of hafnium in hafnium oxide (HfO₂) on dielectric constant, a number of HfTiO₂ compositions including increasing amounts of titanium were tested by simulation. In the simulations, response tensors were predicted for the dielectric materials at both the low and high frequency limits. The simulations were performed on infinitely periodic bulk materials of the dielectrics at 0 K at both the high and low frequency limits. Ti was substituted for a portion of the Hf at levels of 0 mass %, 25 mass %, 40 mass % and 100 mass % of the Hf. The resulting dielectric values are illustrated in FIG. 9. In increasing the amounts of titanium, the dielectric constant of the material increased from about 22 with no Ti present to about 85 when all of the Hf was substituted with Ti.

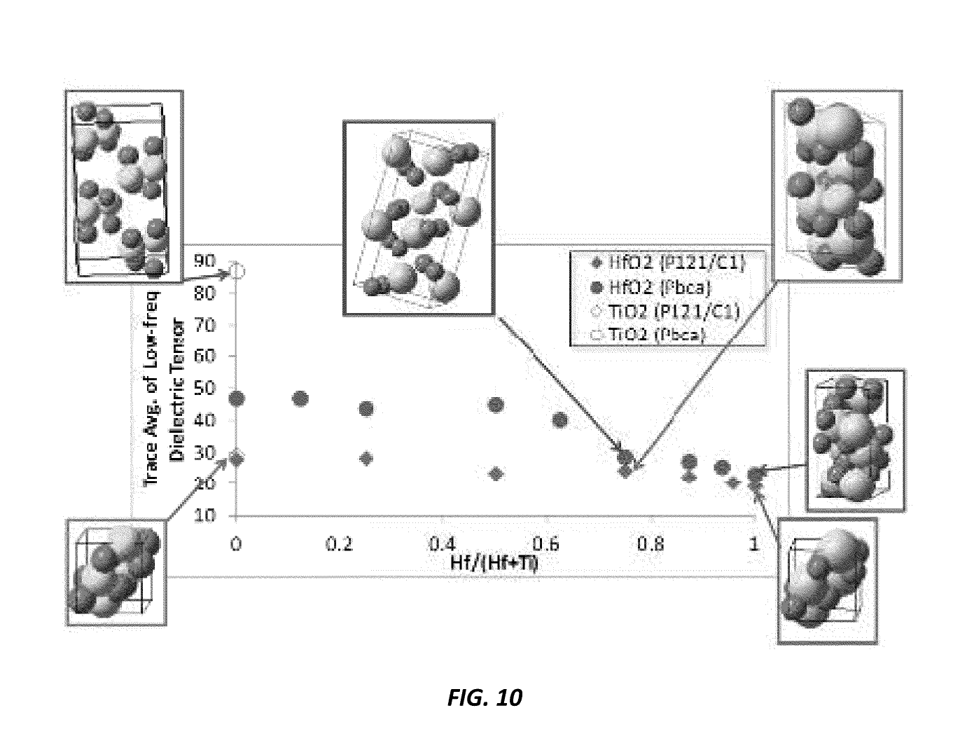

In addition, the crystal structures were predicted. FIG. 10 illustrates the various crystal structures obtained with increasing amounts of Hf present in HfTiO₂. Table 1 provides the dielectric constant of the titanium oxide and hafnium oxide phases present at the difference loadings of Hf and the dielectric constant. As illustrated, with increasing amounts of hafnium, the dielectric constant decreases for the crystal phases.

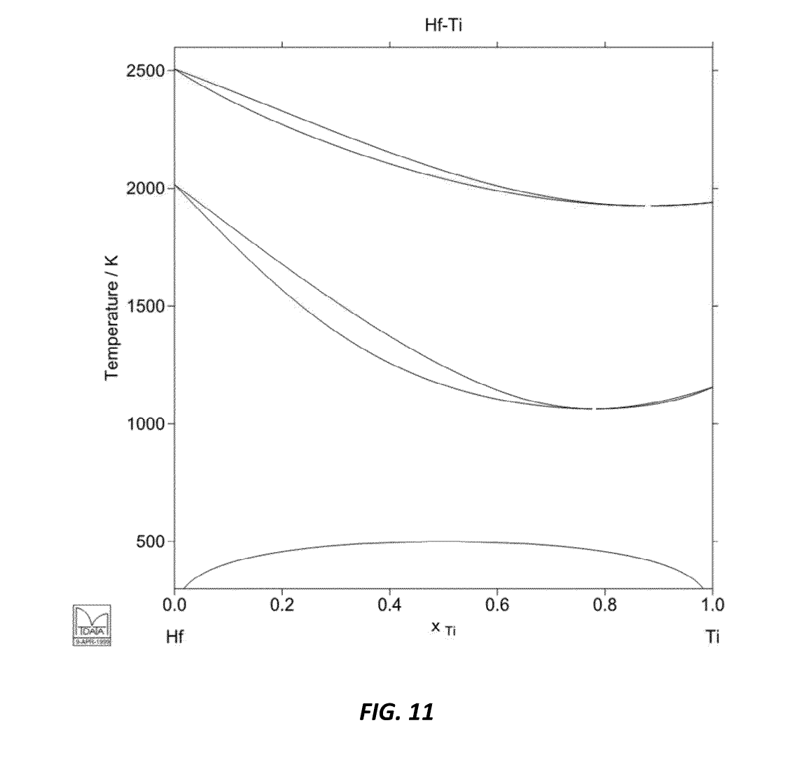

Furthermore, a thermodynamic phase diagram, seen in FIG. 11 was developed based on the simulations that confirm the stability of the Ti-Hf multi-metal oxide. The diagram indicates the chemical stability of the alloy as well as the interfaces with the metal gate and the interlayer dielectric adjacent to the channel.

An aspect of the present disclosure relates to a transistor. The transistor comprises a substrate including a surface, a gate oxide deposited on said substrate surface and a gate deposited on said gate oxide layer. The gate oxide includes one or more dielectric domains and a band gap matrix and the dielectric domains include a first material and said band gap matrix includes a second material. Further, the dielectric constant of said first material is greater than a dielectric constant of said second material and a band gap of said first material is less than a band gap of said second material. In embodiments, the dielectric domain is present at less than 50 mass percent in said gate oxide.

In any of the above embodiments, the difference between the dielectric constant of said first material and the dielectric constant of said second material is 10 or more, and preferably in the range of 10 to 250 and more preferably in the range of 20 to 540. In addition, in embodiments of the above, the dielectric constant of said first material is 20 or greater and preferably 40 to 350 and more preferably 40 to 100. It is also noted that in any of the above embodiments, the dielectric constant of said second material is 25 or less, and preferably in the range of 3 to 25.

Further, in any of the above embodiments the difference between the band gap of said first material and the band gap of said second material is 2 eV or more and preferably in the range of 3 eV to 6 ev. In addition in embodiments of the above, the band gap of said second material is 5 eV or greater, and preferably in the range of 5 eV to 10 eV. It is also noted that in embodiments of the above the band gap of said first material is 5 eV or less, and preferably in the range of 2 eV to 5 eV.

In particular embodiments of the above, the dielectric domains comprise TiO₂ and said band gap matrix is HfO₂.

In any of the above embodiments, the dielectric domains are nanoparticles dispersed within said band gap matrix. Alternatively, or in addition, the dielectric domain is embedded in said band gap material. In another alternative, or in addition, the dielectric domains and said band gap material are present as alternating layers aligned perpendicular to the substrate surface.

In any of the above embodiments, the gate oxide layer has a thickness in the range of 0.1 nm to 5 nm. In addition, any of the above embodiments, the gate is metal. Further, in any of the above embodiments, the substrate surface includes a fin.

Another aspect of the present disclosure relates to an integrated circuit including one or more semiconductor devices, such as those set forth in any of the embodiments of the above. The integrated circuit includes a substrate including a surface, a gate oxide deposited on said substrate surface, and a gate deposited on the gate oxide layer. The gate oxide includes one or more dielectric domains and a band gap matrix. In addition, the dielectric domains include a first material and said band gap matrix includes a second material. Further, the dielectric constant of said first material is greater than a dielectric constant of said second material and a band gap of said first material is less than a band gap of said second material. In embodiments, the dielectric domain is present at less than 50 mass percent in said gate oxide.

In any of the above embodiments, the difference between the dielectric constant of said first material and the dielectric constant of said second material is 10 or more and preferably in the range of 10 to 250 and more preferably in the range of 20 to 540. Further, in embodiments of the above, the dielectric constant of said first material is 20 or greater and preferably in the range of 40 to 350 and more preferably in the range of 40 to 100. In addition, in embodiments of the above the dielectric constant of said second material is 25 or less and preferably in the range of 3 to 25.

In any of the above embodiment, the difference between the band gap of said first material and the band gap of said second material is 2 eV or more and preferably in the range of 3 eV to 6 eV. In addition, in embodiments, the band gap of said second material is 5.0 eV or greater and preferably in the range of 5 eV to 10 eV. Further, in embodiments, the band gap of said first material is 5.0 eV or less, and preferably in the range of 2 eV to 5 eV.

In particular embodiments of the above, the dielectric domains comprise TiO₂ and said band gap matrix is HfO₂.

Further in embodiments of the above, the dielectric domains are nanoparticles dispersed within said band gap matrix. In additional or alternative embodiments of the above, the dielectric domain is embedded in said band gap material. In further additional or alternative embodiments, the dielectric domains and said band gap material are present as alternating layers aligned perpendicular to the substrate surface.

In any of the above embodiments, the gate oxide layer has a thickness in the range of 0.1 nm to 5 nm. Furthermore, in any of the above embodiments the gate is metal. In addition, in any of the above embodiments the substrate surface includes a fin.

Also in various embodiments the integrated circuit is included in a mobile device. Another aspect of the present disclosure relates to a method of preparing an integrated circuit. The method includes forming a gate oxide layer on a surface of a substrate and depositing a gate onto said gate oxide layer. The gate oxide includes one or more dielectric domains and a band gap matrix, wherein said dielectric domains include a first material and said band gap matrix includes a second material. In addition, the dielectric constant of said first material is greater than a dielectric constant of said second material. Further, a band gap of said first material is less than a band gap of said second material. In embodiments, the gate oxide is deposited via atomic layer deposition.

In embodiments of the above, the band gap matrix is deposited, patterned and etched forming one or more trenches in said band gap matrix and said dielectric domains is deposited in said trenches. In embodiments of the above, depositing layers of said band gap matrix by atomic layer deposition and nanoparticles of said dielectric domains are cast intermittently between depositing said layers of said band gap matrix.

In any of the above embodiments, the dielectric domain is present at less than 50 mass percent in said gate oxide. In addition in embodiments, a difference between the dielectric constant of said first material and the dielectric constant of said second material is 10 or more and preferably in the range of 10 to 250 and more preferably in the range of 20 to 540. In embodiments, the constant of said first material is 20 or greater and preferably 40 to 350 and more preferably 40 to 100. In embodiments, the dielectric constant of said second material is 25 or less and preferably in the range of 3 to 25.

In any of the above embodiments, the difference between the band gap of said first material and the band gap of said second material is 2 eV or more and preferably in the range of 3 ev to 6 ev. Further, in embodiments, the band gap of said second material is 5.0 eV or greater and preferably in the range of 5 eV to 10 eV. In addition, in embodiments, the band gap of said first material is 5.0 eV or less, and preferably in the range of 2 eV to 5 eV.

In particular embodiments the dielectric domains comprise TiO₂ and said band gap matrix is HfO₂. Further, in any of the above embodiments, the gate is metal. In addition, in any of the above embodiments, the substrate surface includes a fin.

The foregoing description of several methods and embodiments has been presented for purposes of illustration. It is not intended to be exhaustive or to limit the claims to the precise steps and/or forms disclosed, and obviously many modifications and variations are possible in light of the above teaching. It is intended that the scope of the invention be defined by the claims appended hereto.

What is claimed is:

1. A transistor, comprising:
a substrate including a surface;
a gate oxide deposited on said substrate surface,
wherein said gate oxide includes one or more dielectric domains and a band gap matrix,
wherein said dielectric domains include a first material and said band gap matrix includes a second material,
wherein a dielectric constant of said first material is greater than a dielectric constant of said second material and a band gap of said first material is less than a band gap of said second material; and
a gate deposited on said gate oxide layer.

2. The transistor of claim 1, wherein said dielectric domain is present at less than 50 mass percent in said gate oxide.

3. The transistor of claim 1, wherein a difference between the dielectric constant of said first material and the dielectric constant of said second material is 10 or more.

4. The transistor of claim 1, wherein the dielectric constant of said first material is 20 or greater and the dielectric constant of said second material is 25 or less.

5. The transistor of claim 1, wherein a difference between the band gap of said first material and the band gap of said second material is 2 eV or more.

6. The transistor of claim 1, wherein the band gap of said second material is 5.0 eV or greater and the band gap of said first material is 5.0 eV or less.

7. The transistor of claim 1, wherein said dielectric domains comprise TiO₂ and said band gap matrix is HfO₂.

8. The transistor of claim 1, wherein said gate oxide layer has a thickness in the range of 0.1 nm to 5 nm.

9. An integrated circuit, comprising:
a plurality of transistors including:
a substrate including a surface;
a gate oxide deposited on said substrate surface,
wherein said gate oxide includes one or more dielectric domains and a band gap matrix,
wherein said dielectric domain is present at less than 50 mass percent in said gate oxide,
wherein said dielectric domains include a first material and said band gap matrix includes a second material,
wherein a dielectric constant of said first material is greater than a dielectric constant of said second material and a difference between the dielectric constant of said first material and the dielectric constant of said second material is 10 or more,
wherein a band gap of said first material is less than a band gap of said second material and a difference between the band gap of said first material and the band gap of said second material is 2 eV or more, and
a gate deposited on said gate oxide layer.

10. The integrated circuit of claim 9, wherein the dielectric constant of said first material is 20 or greater and the dielectric constant of said second material is 25 or less.

11. The integrated circuit of claim 9, wherein the band gap of said second material is 5.0 eV or greater and the band gap of said first material is 5.0 eV or less.

12. The integrated circuit of claim 9, wherein said dielectric domains comprise TiO₂ and said band gap matrix is HfO₂.

13. The integrated circuit of claim 9, wherein said gate oxide layer has a thickness in the range of 0.1 nm to 5 nm.

14. The integrated circuit of claim 9, wherein said substrate includes a fin.

15. The integrated circuit of claim 9, wherein said integrated circuit is in a mobile device.

16. A method of preparing a transistor, comprising:
forming a gate oxide layer on a surface of a substrate, wherein said gate oxide includes one or more dielectric domains and a band gap matrix, wherein said dielectric domains include a first material and said band gap matrix includes a second material, wherein a dielectric constant of said first material is greater than a dielectric constant of said second material and a band gap of said first material is less than a band gap of said second material; and
depositing a gate onto said gate oxide layer.

17. The method of claim 16, wherein said gate oxide is deposited via atomic layer deposition.

18. The method of claim 16, wherein said band gap matrix is deposited, patterned and etched forming one or more trenches in said band gap matrix and said dielectric domains is deposited in said trenches.

19. The method of claim 16, wherein depositing layers of said band gap matrix by atomic layer deposition and nanoparticles of said dielectric domains are cast intermittently between depositing said layers of said band gap matrix.

20. The method of claim 16, wherein said dielectric domain is present at less than 50 mass percent in said gate oxide.
